(19) United States
(12) Patent Application Publication
(10) Pub. No.: US 2025/0386490 A1
(43) Pub. Date: Dec. 18, 2025

(54) SEMICONDUCTOR DEVICE

(71) Applicant: Samsung Electronics Co., Ltd., Suwon-si (KR)

(72) Inventors: Kyunghwan NOH, Suwon-si (KR); Boryeon BAE, Suwon-si (KR); Jaehyug LEE, Suwon-si (KR)

(73) Assignee: Samsung Electronics Co., Ltd., Suwon-si (KR)

(21) Appl. No.: 19/230,364

(22) Filed: Jun. 6, 2025

(30) Foreign Application Priority Data
Jun. 12, 2024 (KR) 10-2024-0076616

(51) Int. Cl. H10B 12/00

(52) U.S. Cl. CPC H10B 12/50; H10B 12/09; H10B 12/315

(57) ABSTRACT

A semiconductor device including an upper insulating layer. In a cell area, the upper insulating layer may be in contact with a cell capping pattern, and in a core area the upper insulating layer is arranged to penetrate an insulating thin layer to be in contact with each of a core capping pattern, an insulating spacer, and an insulating thin layer.

### CROSS-REFERENCE TO RELATED APPLICATION

This application is based on and claims priority under 35 U.S.C. § 119 to Korean Patent Application No. 10-2024-0076616 filed on Jun. 12, 2024, in the Korean Intellectual Property office, the disclosure of which is incorporated by reference herein in its entirety.

### BACKGROUND

The inventive concepts relate to semiconductor devices, and more particularly, to semiconductor devices including a cell area and a core area.

Electronic devices have gradually become increasingly compact and lighter according to rapid development of the electronics industry and demands of users. Accordingly, semiconductor devices having a high degree of integration used in the electronic devices are required, and design rules for components of the semiconductor devices are continuously reduced. Accordingly, the difficulty of the manufacturing process for forming the fine patterns constituting the semiconductor devices is gradually increasing.

### SUMMARY

Some example embodiments of the inventive concepts provide a semiconductor device capable of improving product reliability, by reducing bonding defects of a bit line structure by reducing a boundary surface between patterns constituting the bit line structure.

The technical advantages provided by the inventive concepts are not limited to the above-mentioned advantages, and other unstated technical advantages may be clearly understood by those of ordinary skill in the art from the following descriptions.

Some example embodiments of the inventive concepts provide a semiconductor device that includes a substrate including a cell area and a core area surrounding the cell area, the cell area including a cell active region and the core area including a core active region; a direct contact and a bit line structure both in the cell area, the direct contact being connected to the cell active region and the bit line structure being in contact with the direct contact, the bit line structure including a cell capping pattern at an upper portion thereof; a gate structure on the substrate in the core area, the gate structure including a core capping pattern at an upper portion of the gate structure; an insulating spacer on both sidewalls of the gate structure; an insulating thin layer conformally surrounding the insulating spacer; and an upper insulating layer covering the cell capping pattern of the bit line structure in the cell area, and covering the core capping pattern of the gate structure in the core area. In the cell area, the upper insulating layer contacts the cell capping pattern. In the core area, the upper insulating layer penetrates the insulating thin layer, and contacts each of the core capping pattern, the insulating spacer, and the insulating thin layer.

Some example embodiments of the inventive concepts further provide a semiconductor device that includes a substrate including a cell area and a core area surrounding the cell area, the cell area including a cell active region and the core area including a core active region; a direct contact and a bit line structure both in the cell area, the direct contact being connected to the cell active region and the bit line structure being in contact with the direct contact, the bit line structure including a cell capping pattern at an upper portion thereof; a gate structure on the substrate in the core area, the gate structure including a core capping pattern at an upper portion of the gate structure; an insulating spacer on both sidewalls of the gate structure; an insulating thin layer conformally surrounding the insulating spacer; an interlayer insulating layer surrounding a periphery of the gate structure in the core area; a natural oxide layer covering the cell capping pattern of the bit line structure in the cell area, and the natural oxide layer conformally covering the core capping pattern of the gate structure and the interlayer insulating layer in the core area; and an upper insulating layer covering the natural oxide layer in the cell area and the core area. The natural oxide layer is between the cell capping pattern and the upper insulating layer in the cell area. In the core area, the natural oxide layer penetrates the insulating thin layer and contacts each of the core capping pattern, the insulating spacer, and the insulating thin layer.

Some example embodiments of the inventive concepts still further provide a semiconductor device that includes a substrate including a cell area and a core area surrounding the cell area, the cell area including a cell active region and the core area including a core active region; a direct contact and a bit line structure both in the cell area, the direct contact being connected to the cell active region and the bit line structure being in contact with the direct contact, the bit line structure including a cell conductive pattern and a cell capping pattern; a gate structure on the substrate in the core area, the gate structure including a core conductive pattern and a core capping pattern; an insulating spacer on both sidewalls of the gate structure; an insulating thin layer conformally surround the insulating spacer; an interlayer insulating layer surrounding a periphery of the gate structure in the core area; and an upper insulating layer covering the cell capping pattern of the bit line structure in the cell area, and the upper insulating layer conformally covering the core capping pattern of the gate structure and the interlayer insulating layer in the core area. In the cell area, the upper insulating layer contacts the cell capping pattern. In the core area, the interlayer insulating layer has a concavely rounded upper surface, and the upper insulating layer has a convexly rounded lower surface corresponding to the concavely rounded upper surface of the interlayer insulating layer.

### BRIEF DESCRIPTION OF THE DRAWINGS

Embodiments will be more clearly understood from the following detailed description taken in conjunction with the accompanying drawings in which:

FIG. 1 is a plan view of a schematic configuration of a semiconductor device, according to some example embodiments;

FIG. 2 is a planar layout of main components of a memory cell array area of a semiconductor device, according to some example embodiments;

FIG. 3 is a cross-sectional view of main components of a semiconductor device, according to some example embodiments;

FIG. 4 is a cross-sectional view of main components of a semiconductor device, according to some example embodiments;

FIG. 5 is a flowchart of a manufacturing method of a semiconductor device, according to some example embodiments;

FIGS. 6, 7, 8, 9, 10, 11, 12, 13, 14, 15, 16 and 17 are cross-sectional views illustrating a manufacturing method of a semiconductor device, according to some example embodiments; and

FIG. 18 is a configuration diagram of a system including a semiconductor device, according to some example embodiments.

### DETAILED DESCRIPTION

Hereinafter, some example embodiments of the inventive concepts are described in detail with reference to the accompanying drawings.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

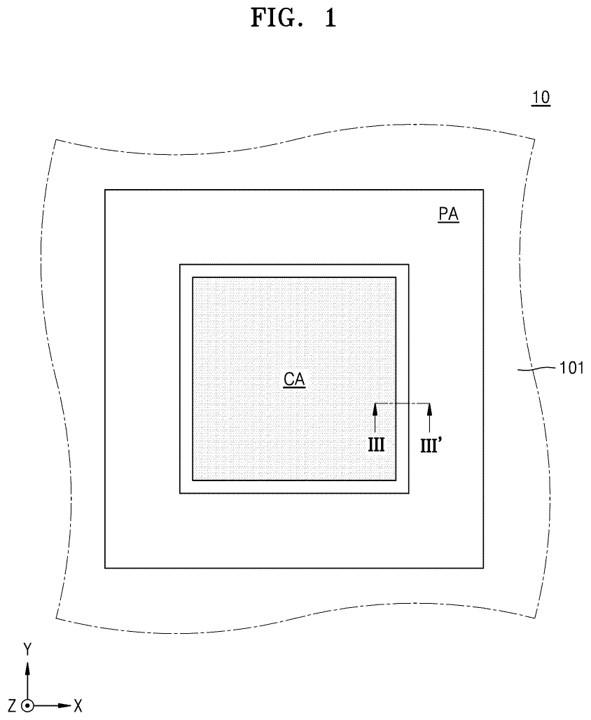

FIG. 1 is a plan view of a schematic configuration of a semiconductor device 10, according to some example embodiments.

Referring to FIG. 1, the semiconductor device 10 may include a substrate 101 including a cell area CA, a core area PA surrounding the cell area CA, and an interface area between the cell area CA and the core area PA.

The substrate 101 may include a wafer including silicon (Si). In some example embodiments, the substrate 101 may include a wafer including a semiconductor element such as germanium (Ge), or a compound semiconductor such as silicon carbide (SiC), gallium arsenide (GaAs), indium arsenide (InAs), and indium phosphide (InP). In some example embodiments, the substrate 101 may have a silicon on insulator (SOI) structure. The substrate 101 may include a conductive area, for example, a well doped with a dopant, or a structure doped with a dopant.

In some example embodiments, the cell area CA may include a memory cell area of the semiconductor device 10. The cell area CA may constitute a memory cell array area of a volatile memory device, or a memory cell array area of a non-volatile memory device. The memory cell array area may include a memory cell array area, such as dynamic random access memory (RAM) (DRAM), magnetic RAM (MRAM), static RAM (SRAM), phase change RAM (PRAM), resistance RAM (RRAM), and ferroelectric RAM (FRAM). The cell area CA may include a unit memory cell including a transistor and a capacitor, or a unit memory cell including a switching device and a variable resistor.

In the core area PA, a peripheral circuit required for driving the unit memory cell in the cell area CA may be arranged.

In the interface area, a plurality of conductive lines installed to enable an electrical connection between the cell area CA and the core area PA, and an insulating structure for insulation between the cell area CA and the core area PA may be arranged.

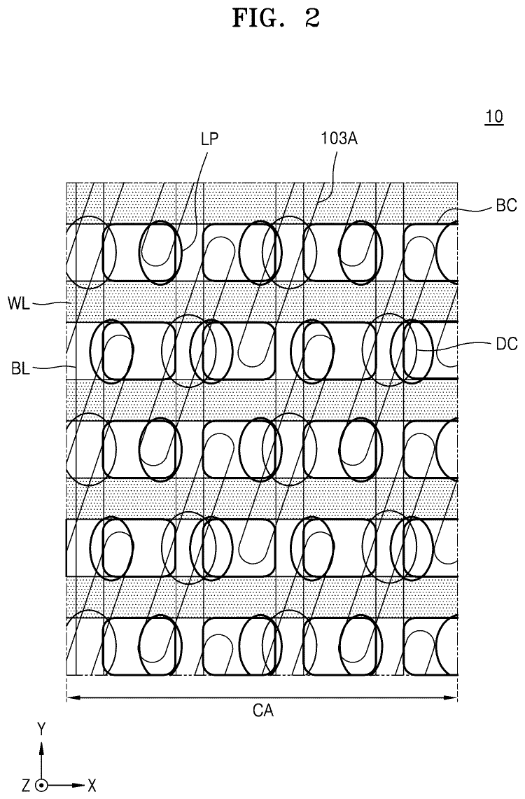

FIG. 2 is a planar layout of main components of a memory cell array area of the semiconductor device 10, according to some example embodiments.

Referring to FIG. 2, the semiconductor device 10 may include a plurality of cell active regions 103A arranged to have a major axis in a diagonal direction with respect to a first direction (X direction) and a second direction (Y direction).

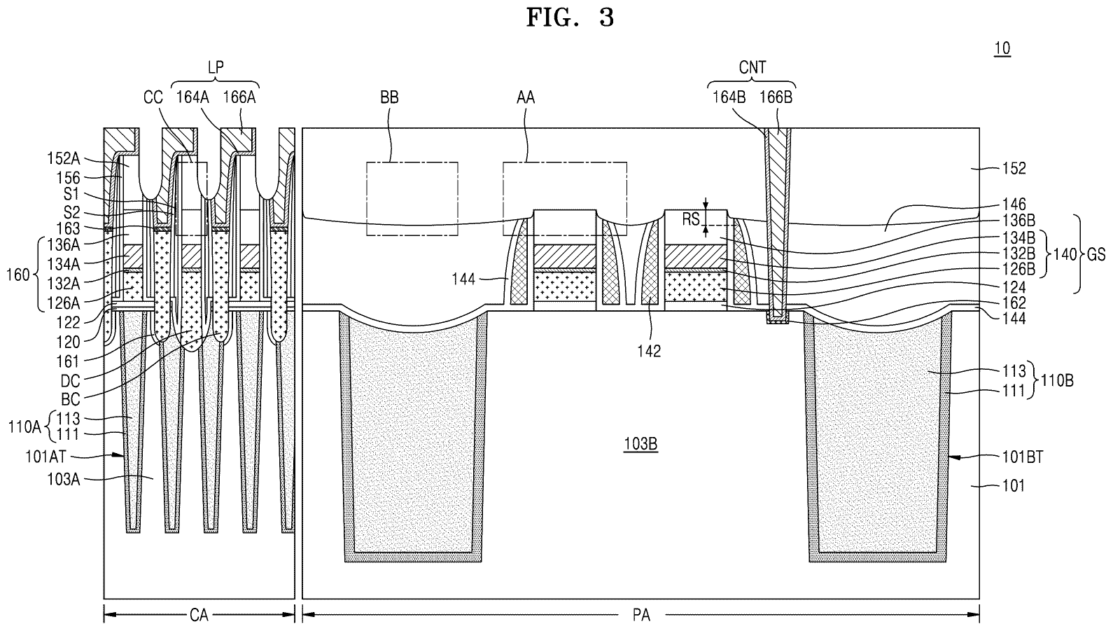

According to the inventive concepts, an active region formed in the cell area CA may be referred to as the cell active region 103A, and an active region formed in the core area (refer to PA in FIG. 3) other than the cell area CA may be differentially referred as a core active region (103B in FIG. 3).

A plurality of word lines WL may extend in parallel with each other in the first direction (X direction) across the plurality of cell active regions 103A. On the plurality of word lines WL, a plurality of bit lines BL may extend in parallel with each other in the second direction (Y direction) crossing the first direction (X direction).

The plurality of bit lines BL may be connected to the plurality of cell active regions 103A via a plurality of direct contacts DC, respectively. In some example embodiments, a buried contact BC may be formed between two adjacent bit lines BL among the plurality of bit lines BL. The buried contact BC may extend to an upper portion of any one bit line BL of two bit lines BL adjacent to each other. In some example embodiments, the plurality of buried contacts BC may be arranged in a line in the first direction (X direction) and the second direction (Y direction).

A plurality of landing pads LP may be respectively formed on the plurality of buried contacts BC. The plurality of buried contacts BC and the plurality of landing pads LP may respectively connect lower electrodes of capacitors (not illustrated) formed on the plurality of bit lines BL to the plurality of cell active regions 103A. The plurality of landing pads LP may be arranged to partially overlap the plurality of buried contacts BC.

FIG. 3 illustrates main components of the semiconductor device 10 according to some example embodiments, and is a cross-sectional view taken along line III-III′ in FIG. 1.

Referring to FIG. 3, the semiconductor device 10 may include the substrate 101 having the cell area CA and the core area PA.

In the substrate 101, a cell trench isolation 110A filling a cell trench 101AT may be formed in the cell area CA, and a core trench isolation 110B filling a core trench 101BT may be formed in the core area PA. Because descriptions of the substrate 101 are the same as those given above, a detailed description of the substrate 101 is omitted.

A width of the cell trench isolation 110A arranged in the cell area CA may be less than a width of the core trench isolation 110B arranged in the core area PA. Each of the cell trench isolation 110A and the core trench isolation 110B may include a silicon oxide layer, a silicon nitride layer, or a combination thereof. Each of the cell trench isolation 110A and the core trench isolation 110B may include a single layer including one type of insulating layer, or a multilayer including a combination of at least two types of insulating layers. In some example embodiments, each of the cell trench isolation 110A and the core trench isolation 110B may include a first insulating pattern 111 on the periphery thereof and a second insulating pattern 113 inside thereof.

The plurality of cell active regions 103A may be defined in the cell area CA of the substrate 101 by the cell trench isolation 110A, and the core active region 103B may be defined in the core area PA of the substrate 101 by the core trench isolation 110B.

Although not illustrated, a plurality of word line trenches may be formed in the substrate 101 in the cell area CA. The plurality of word line trenches may extend in parallel with each other, and may have a line shape respectively crossing the plurality of cell active regions 103A. The plurality of word lines (refer to WL in FIG. 2) may be respectively arranged inside the plurality of word line trenches.

In some example embodiments, after the word line (refer to WL in FIG. 2) is formed, impurity ions may be implanted into the substrate 101 at both sides of the word line (refer to WL in FIG. 2), and source/drain regions may be formed on upper surfaces of the plurality of cell active regions 103A. In some example embodiments, before the plurality of word lines WL (refer to FIG. 2) are formed, impurity ions for forming the source/drain regions may be implanted.

In the cell area CA, a first surface insulating layer 120 and a second surface insulating layer 122 may be sequentially arranged on the substrate 101. The first surface insulating layer 120 may include a silicon oxide layer, and the second surface insulating layer 122 may include a silicon nitride layer, but some example embodiments are not limited to them.

In the cell area CA, a plurality of bit line structures 160 may extend in parallel with each other on the substrate 101 in a direction crossing the word line (refer to WL in FIG. 2). The plurality of bit line structures 160 may be connected to the plurality of cell active regions 103A via the plurality of direct contacts DC, respectively.

The plurality of bit line structures 160 may include a first cell conductive pattern 126A, a second cell conductive pattern 132A, a third cell conductive pattern 134A, and a cell capping pattern 136A. An upper insulating pattern 152A may be arranged on the cell capping pattern 136A.

A gate structure GS may be formed in the core area PA. The gate structure GS may be formed on the core active region 103B. The gate structure GS may include a gate dielectric layer 124, a gate electrode 140, and a core capping pattern 136B. The gate electrode 140 may include a first core conductive pattern 126B, a second core conductive pattern 132B, and a third core conductive pattern 134B on the gate dielectric layer 124. The gate electrode 140 may be covered by the core capping pattern 136B.

The gate dielectric layer 124 may include at least one of a silicon oxide layer, a silicon nitride layer, a silicon oxynitride layer, an oxide/nitride/oxide (ONO) layer, and a high-k dielectric material layer having a higher dielectric constant than the silicon oxide layer. For example, the gate dielectric layer 124 may include a material layer having a dielectric constant of about 10 to about 25.

In the core area PA, an insulating spacer 142 arranged on both sidewalls of the gate structure GS, and an insulating thin layer 144 covering the substrate 101 and the gate structure GS and surrounding the insulating spacer 142 may be formed. In some example embodiments, the insulating spacer 142 may include a silicon oxide layer, a silicon nitride layer, or a combination thereof, and the insulating thin layer 144 may include a silicon nitride layer, but some example embodiments are not limited thereto.

In the semiconductor device 10 according to some example embodiments, a lowermost surface of the insulating spacer 142 may have a higher vertical level than a lowermost surface of the gate structure GS, and an uppermost surface of the insulating spacer 142 may have a lower vertical level than an uppermost surface of the gate structure GS.

The uppermost surface of the insulating spacer 142 may contact an upper insulating layer 152 to be described below, and sidewalls and a lower surface of the insulating spacer 142 may contact the insulating thin layer 144.

In the core area PA, an interlayer insulating layer 146 may surround the gate structure GS and the insulating thin layer 144. In some example embodiments, the interlayer insulating layer 146 may include a silicon oxide layer formed by using a high density plasma (HDP) process or a flowable chemical vapor deposition (FCVD) process, but is not limited thereto.

In the core area PA, the upper insulating layer 152 may be arranged on the core capping pattern 136B and the interlayer insulating layer 146. The upper insulating layer 152 of the core area PA may be formed by using the same manufacturing process as a component corresponding to the upper insulating pattern 152A of the cell area CA, and accordingly, the upper insulating layer 152 and the upper insulating pattern 152A may include the same material. In some example embodiments, the upper insulating layer 152 and the upper insulating pattern 152A may include a silicon nitride layer.

In the cell area CA of the semiconductor device 10 of the inventive concepts, like in portion CC, the upper insulating pattern 152A may directly contact the cell capping pattern 136A. For example, in the cell area CA, the upper insulating pattern 152A and the cell capping pattern 136A may form a bonding interface between the silicon nitride layers.

In the core area PA of the semiconductor device 10 of the inventive concepts, like in portion AA, the upper insulating layer 152 may be arranged to penetrate the insulating thin layer 144 downward and contact all (e.g., each) of the core capping pattern 136B, the insulating spacer 142, and the insulating thin layer 144. For example, the upper insulating layer 152 in the core area PA may contact the core capping pattern 136B, the insulating spacer 142 and the insulating thin layer 144. For example, the upper insulating layer 152 may have a lower surface convexly rounded in a downward direction.

Accordingly, in the cell area CA, a lowermost surface of the upper insulating pattern 152A may have a higher vertical level than a lowermost surface of the upper insulating layer 152. In the core area PA, the lowermost surface of the upper insulating layer 152 may have a lower vertical level than an uppermost surface of the core capping pattern 136B. For example, a level difference RS between the uppermost surface of the core capping pattern 136B and the lowermost surface of the upper insulating layer 152 may be at least about 100 angstroms (Å).

In the semiconductor device 10 of the inventive concepts, the insulating thin layer 144 may conformally cover a rounded upper surface of the core trench isolation 110B. Like in portion BB, the interlayer insulating layer 146 may have a concavely rounded upper surface in the downward direction. This may be a characteristic due to a polishing process of the insulating thin layer 144 to be described below. The interlayer insulating layer 146 may have a convexly rounded lower surface in the downward direction.

Accordingly, the rounded upper surface of the interlayer insulating layer 146 and the rounded lower surface of the upper insulating layer 152 may correspond to each other. The rounded upper surface of the core trench isolation 110B and the rounded lower surface of the interlayer insulating layer 146 may correspond to each other.

The direct contact DC may be in the cell area CA. In the cell area CA, in a space between adjacent ones of the plurality of bit line structures 160, the plurality of buried contacts BC and the plurality of landing pads LP respectively connected to the plurality of buried contacts BC may be arranged.

In the cell area CA, the plurality of landing pads LP may include a first conductive barrier layer 164A and a first conductive layer 166A. The first conductive barrier layer 164A may have a Ti/TiN stacked structure. The first conductive layer 166A may include deposited polysilicon, metal, metal silicide, conductive metal nitride, or a combination thereof. For example, the first conductive layer 166A may include tungsten (W).

In the core area PA, a contact plug CNT may include a second conductive barrier layer 164B and a second conductive layer 166B. The second conductive barrier layer 164B and the second conductive layer 166B may include substantially the same material as the first conductive barrier layer 164A and the first conductive layer 166A described above.

In the cell area CA, the plurality of landing pads LP may be electrically connected to the plurality of cell active regions 103A, respectively, and in the core area PA, the contact plug CNT may be electrically connected to the core active region 103B.

In the cell area CA, an insulating liner 156 and spacer structures S1 and S2 covering the insulating liner 156 may be arranged on sidewalls of each of the plurality of bit line structures 160. Between two adjacent bit line structures 160 among the plurality of bit line structures 160, a first metal silicide layer 161 may be arranged on a surface of the cell active region 103A, the buried contact BC connected to the cell active region 103A may be arranged, and a second metal silicide layer 163 may be arranged on the buried contact BC.

In some example embodiments, the spacer structures S1 and S2 may include a silicon oxide layer, a silicon nitride layer, air, or a combination thereof. For example, a case in which the spacer structures S1 and S2 include a double layer is illustrated, but the spacer structures S1 and S2 may include a single layer or a triple layer.

In some example embodiments, the first metal silicide layer 161 may include cobalt silicide, but is not limited thereto. In some example embodiments, the first metal silicide layer 161 may be omitted. The buried contact BC may include doped polysilicon. In some example embodiments, the second metal silicide layer 163 may include cobalt silicide, but is not limited thereto. In some example embodiments, the second metal silicide layer 163 may be omitted.

Electronic devices have become more compact and lighter according to rapid development of the electronics industry and demands of users. Accordingly, semiconductor devices 10 having a high degree of integration used in the electronic devices are required, and thus, design rules for components of the semiconductor devices 10 are continuously reduced. Accordingly, the difficulty of the manufacturing process for forming the fine patterns constituting the semiconductor devices 10 is gradually increasing.

Accordingly, in the general semiconductor device such as the semiconductor device 10 including fine patterns, a stacked structure of the bit line structure 160 and a plurality of insulating patterns arranged on the bit line structure 160 may have a very large aspect ratio. In the stacked structure of the plurality of insulating patterns, an undesired residue thin layer may be formed on the bonding interface therebetween due to characteristics of a manufacturing process. As a result, due to the formation of a stacked structure with a very large aspect ratio in which different materials are stacked, issues such as poor bonding of the bit line structure 160 are likely to occur.

To solve this issue, the semiconductor device 10 according to some example embodiments of the inventive concepts may, in the cell area CA, include the upper insulating pattern 152A and the cell capping pattern 136A by using the same insulating material, and may arrange the upper insulating pattern 152A and the cell capping pattern 136A to be in direct contact. In this process, the upper insulating layer 152 of the core area PA corresponding to the upper insulating pattern 152A may be formed to penetrate the insulating thin layer 144 in a downward direction to contact all of the core capping pattern 136B, the insulating spacer 142, and the insulating thin layer 144.

Accordingly, in some example embodiments of the inventive concepts defects in the manufacturing process of the semiconductor device 10 may be significantly reduced, and thus, product reliability and/or economic feasibility of the semiconductor device 10 may be improved.

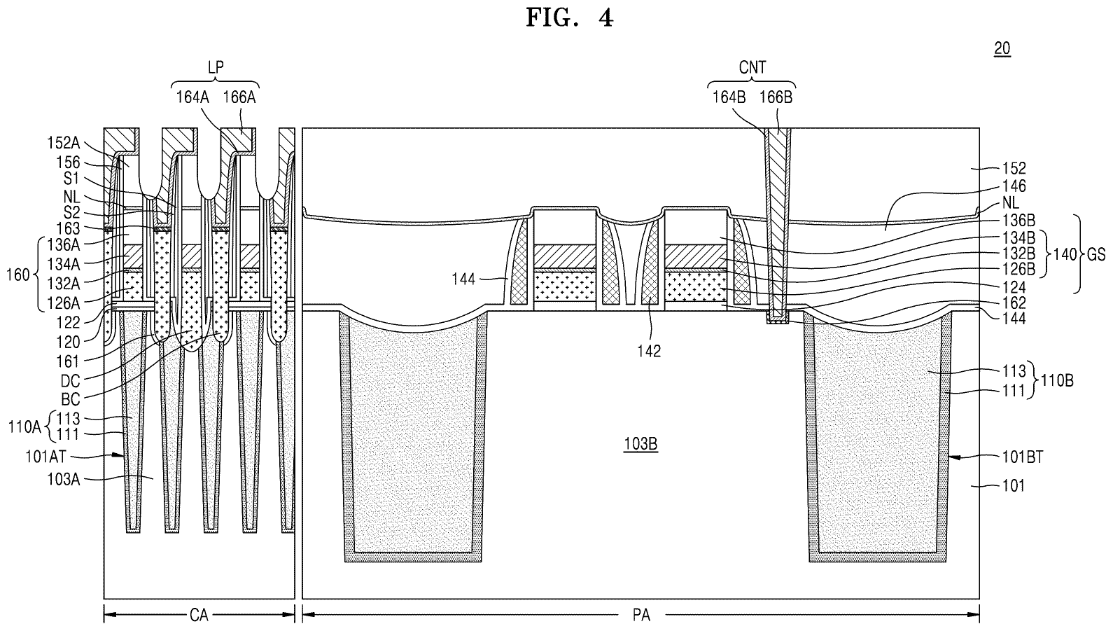

FIG. 4 is a cross-sectional view of main components of a semiconductor device 20, according to some example embodiments.

Most of components constituting the semiconductor device 20 and materials included in the components to be described below may be substantially the same as or similar to those described with reference to FIGS. 1 through 3. Accordingly, for convenience of description, the differences from the semiconductor device 10 described above are mainly described.

Referring to FIG. 4, the semiconductor device 20 includes a natural oxide layer NL formed on the substrate 101 including the cell area CA and the core area PA surrounding the cell area CA.

The semiconductor device 20 of the inventive concepts may include the natural oxide layer NL which covers the cell capping pattern 136A of the bit line structure 160 in the cell area CA, and conformally covers the core capping pattern 136B of the gate structure GS and the interlayer insulating layer 146 in the core area PA.

The natural oxide layer NL may include a material layer which is naturally generated, after a process of forming the cell capping pattern 136A, the core capping pattern 136B, and the interlayer insulating layer 146. For example, an additional process for forming the natural oxide layer NL may not be required.

The semiconductor device 20 of the inventive concepts may include the upper insulating pattern 152A covering the natural oxide layer NL in the cell area CA and the upper insulating layer 152 covering the natural oxide layer NL in the core area PA.

Accordingly, in the cell area CA, the natural oxide layer NL may be arranged between the cell capping pattern 136A and the upper insulating pattern 152A, and in the core area PA, the natural oxide layer NL may be arranged to penetrate the insulating thin layer 144 to be in contact with the core capping pattern 136B, the insulating spacer 142, and the insulating thin layer 144.

Accordingly, the lowermost surface of the upper insulating pattern 152A in the cell area CA may have a higher vertical level than the lowermost surface of the upper insulating layer 152 in the core area PA. In the core area PA, the lowermost surface of the upper insulating layer 152 may have a lower vertical level than the uppermost surface of the core capping pattern 136B.

In the semiconductor device 20 of the inventive concepts, the insulating thin layer 144 may be conformally arranged to be in contact with both sidewalls of the gate structure GS and the upper surface of the substrate 101, the uppermost surface of the insulating spacer 142 may be in contact with the natural oxide layer NL, and the sidewalls and the lower surface of the insulating spacer 142 may be arranged to be in contact with the insulating thin layer 144.

The semiconductor device 20 of the inventive concepts may include an interlayer insulating layer 146 surrounding the periphery of the gate structure GS in the core area PA and having a concavely rounded upper surface in the downward direction, and the natural oxide layer NL may be arranged to conformally cover the rounded upper surface of the interlayer insulating layer 146.

In the cell area CA of the semiconductor device 20 of the inventive concepts, the bit line structure 160 may include the natural oxide layer NL between the silicon nitride layers constituting the upper insulating pattern 152A and the cell capping pattern 136A.

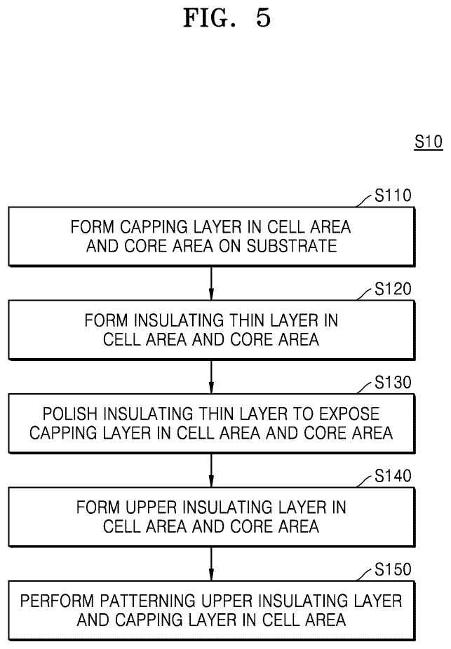

FIG. 5 is a flowchart of manufacturing method S10 of a semiconductor device, according to some example embodiments.

Referring to FIG. 5, the manufacturing method S10 of a semiconductor device may have a process sequence of first through fifth operations (S110 through S150).

When a certain embodiment is implemented differently, a particular process sequence may also be executed differently from the sequence to be described. For example, two consecutively described processes may also be performed substantially at the same time or in a sequence opposite to the sequence to be described.

The manufacturing method S10 of a semiconductor device according to some example embodiments of the inventive concepts may include first operation S110 of forming a capping layer in the cell area and the core area on a substrate, second operation S120 of forming an insulating thin layer in the cell area and the core area, third operation S130 of polishing the insulating thin layer to expose the capping layer in the cell area and the core area, fourth operation S140 of forming an upper insulating layer in the cell area and the core area, and fifth operation S150 of patterning the upper insulating layer and the capping layer in the cell area.

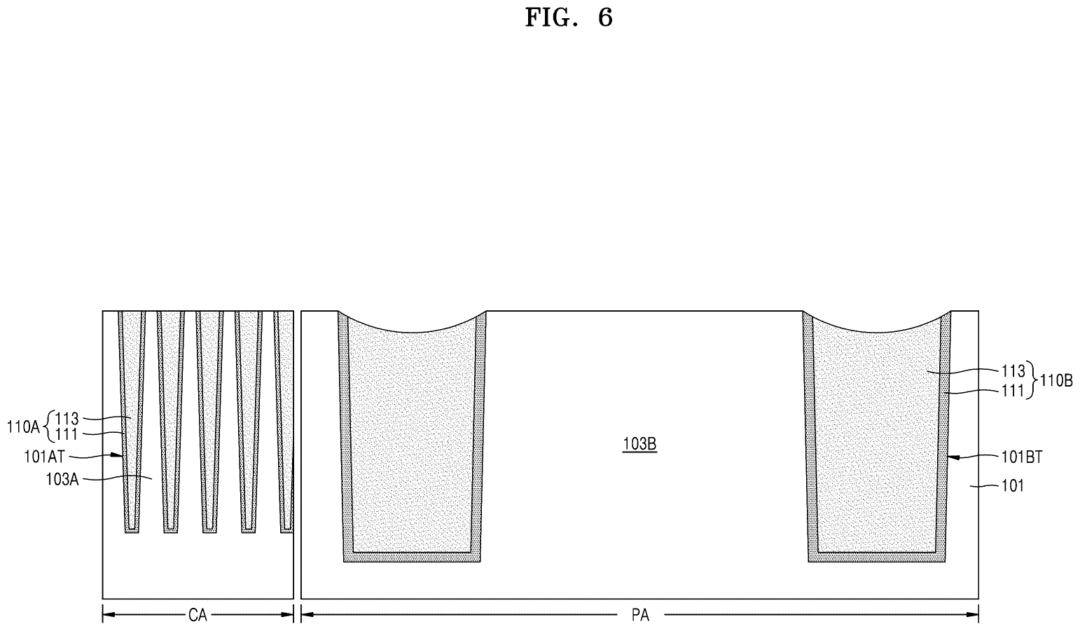

Technical characteristics of each of first through fifth operations S110 through S150 are described in detail below with reference to FIGS. 6 through 17.

FIGS. 6 through 17 are cross-sectional views illustrating a manufacturing method of a semiconductor device, according to some example embodiments.

Referring to FIG. 6, on the prepared substrate 101, the cell trench isolation 110A filling the cell trench 101AT in the cell area CA may be simultaneously formed with the core trench isolation 110B filling the core trench 101BT in the core area PA.

Each of the cell trench isolation 110A and the core trench isolation 110B may include a first insulating pattern 111 on the periphery thereof and a second insulating pattern 113 inside thereof.

The first insulating pattern 111 may include a silicon oxide layer formed by using a thermal oxidation process. The first insulating pattern 111 formed by using the thermal oxidation process may have good interfacial characteristics with the substrate 101, and may include the silicon oxide layer of good quality.

The first insulating pattern 111 and the second insulating pattern 113 may be manufactured by using different processes, but may include the same material. That is, both the first insulating pattern 111 and the second insulating pattern 113 may include a silicon oxide layer.

A width of the core trench isolation 110B in the core area PA in the horizontal direction may be greater than a width of the cell trench isolation 110A in the horizontal direction in the cell area CA. Accordingly, the core trench isolation 110B may have a concavely rounded upper surface in the downward direction, compared to the cell trench isolation 110A.

Each of the cell trench isolation 110A and the core trench isolation 110B may include a shallow trench isolation (STI) layer.

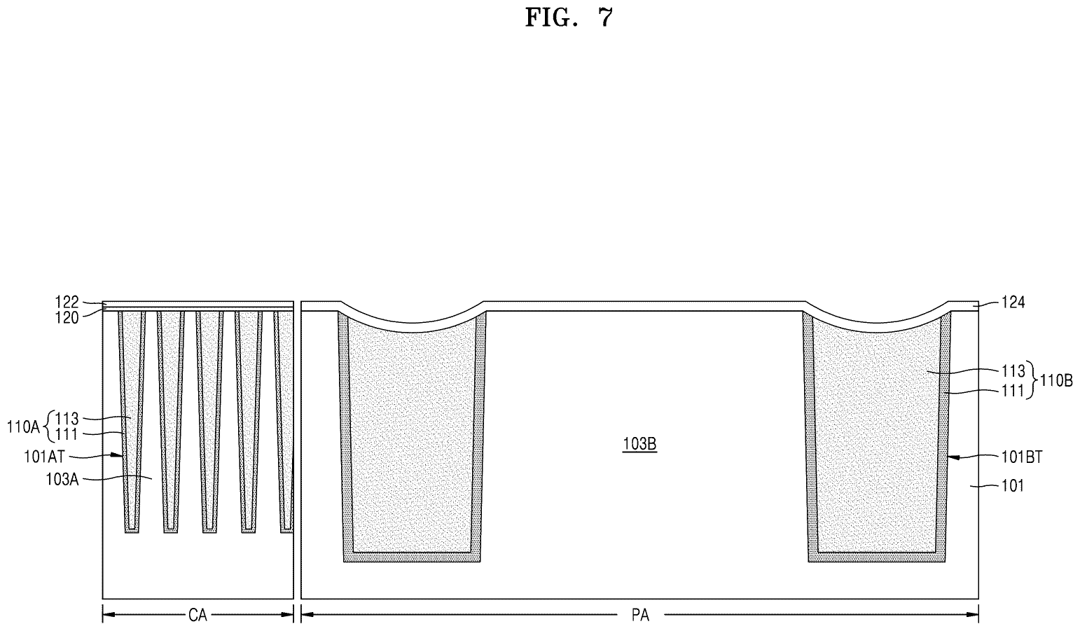

Referring to FIG. 7, the cell active region 103A may be defined by a cell trench isolation 110A in the cell area CA, and the core active region 103B may be defined by the core trench isolation 110B in the core area PA.

A plurality of word line trenches (not illustrated) may be formed in the substrate 101 in the cell area CA. The plurality of word line trenches may extend in parallel with each other, and may have a line shape respectively crossing the plurality of cell active regions 103A. The plurality of word lines (refer to WL in FIG. 2) may be respectively arranged inside the plurality of word line trenches.

After the first surface insulating layer 120 and the second surface insulating layer 122 are sequentially formed on the substrate 101 in the cell area CA and the core area PA, in the core area PA, the first surface insulating layer 120 and the second surface insulating layer 122 may be removed to expose the plurality of core active regions 103B of the substrate 101 again. Next, while the cell area CA is covered with a mask pattern (not illustrated), the gate dielectric layer 124 may be formed on the substrate 101 in the core area PA.

The first surface insulating layer 120 may include a silicon oxide layer, and the second surface insulating layer 122 may include a silicon nitride layer, but some example embodiments are not limited to them. In the core area PA, impurities may be removed from the surface of the substrate 101 of the core area PA before forming the gate dielectric layer 124, by forming and removing the first surface insulating layer 120 and the second surface insulating layer 122. In this manner, the quality of the gate dielectric layer 124 in the core area PA may be improved.

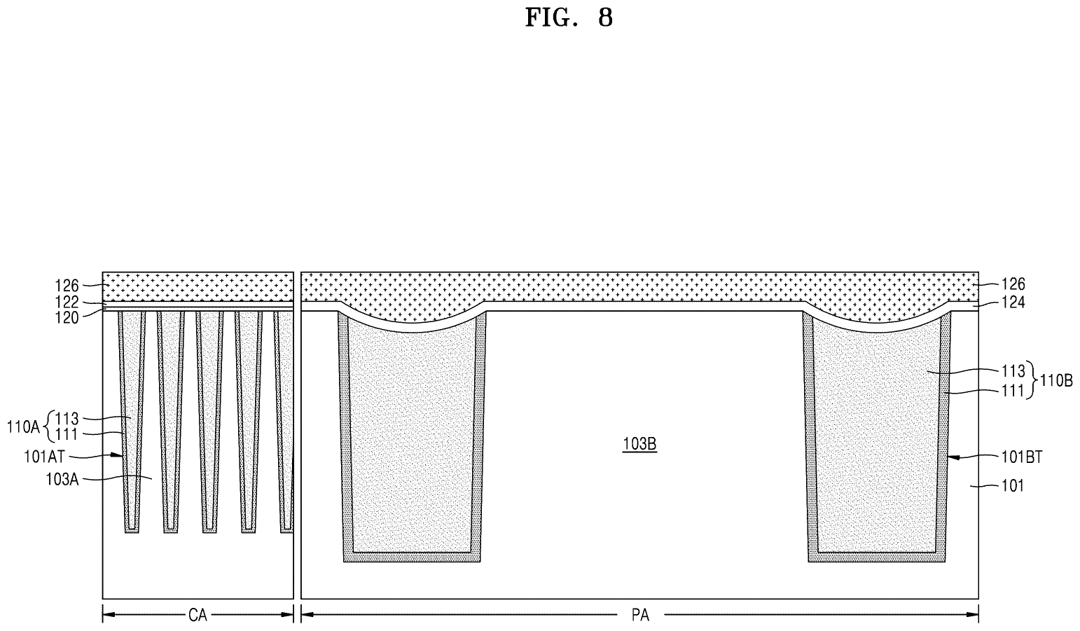

Referring to FIG. 8, a first preliminary conductive layer 126 may be formed on the substrate 101 in the cell area CA and the core area PA.

The first preliminary conductive layer 126 may include polysilicon, but the embodiment is not limited thereto. The first preliminary conductive layer 126 may be formed to fill a space caused by the rounded upper surface of the core trench isolation 110B in the core area PA.

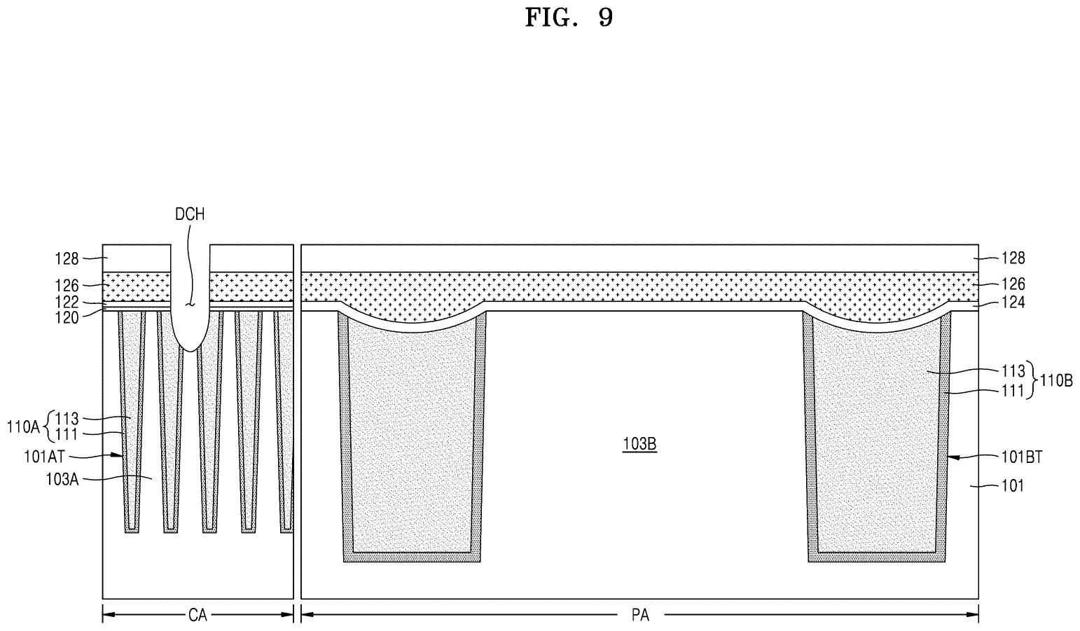

Referring to FIG. 9, a mask pattern 128 may be formed on the first preliminary conductive layer 126 in the cell area CA and the core area PA.

The mask pattern 128 may include an opening partially exposing the first preliminary conductive layer 126 in the cell area CA. The core area PA may be covered by the mask pattern 128, and may not be exposed to the outside.

Next, the first preliminary conductive layer 126 exposed in the opening of the mask pattern 128 may be etched, and by etching a portion of the substrate 101 and a portion of the cell trench isolation 110A, which are exposed as the result of the etching, a direct contact hole DCH exposing the cell active region 103A of the substrate 101 may be formed.

The mask pattern 128 may include a hard mask pattern including a silicon oxide layer or a silicon nitride layer. A photolithography process may be used to form the mask pattern 128.

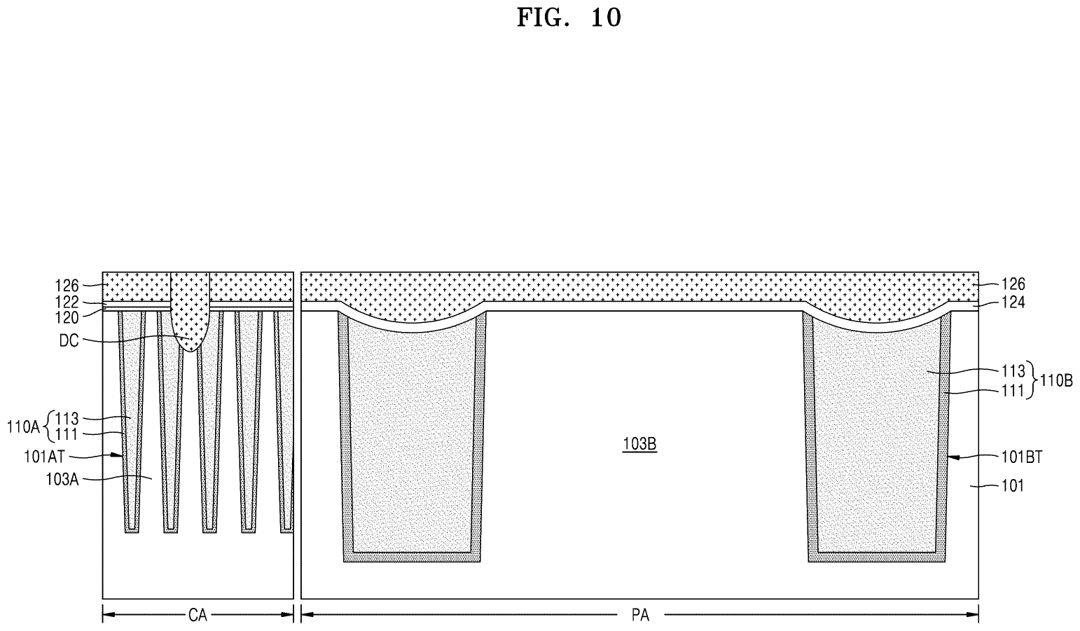

Referring to FIG. 10, after the mask pattern (refer to 128 in FIG. 9) is removed, a conductive layer having a thickness sufficient to fill the direct contact hole DCH may be formed inside the direct contact hole (refer to DCH in FIG. 9) and above the first preliminary conductive layer 126.

By etching back the conductive layer so that the conductive layer remains only inside the direct contact hole DCH, the direct contact DC formed of the conductive layer remaining inside the direct contact hole DCH may be formed. The conductive layer may include doped polysilicon, but is not limited thereto.

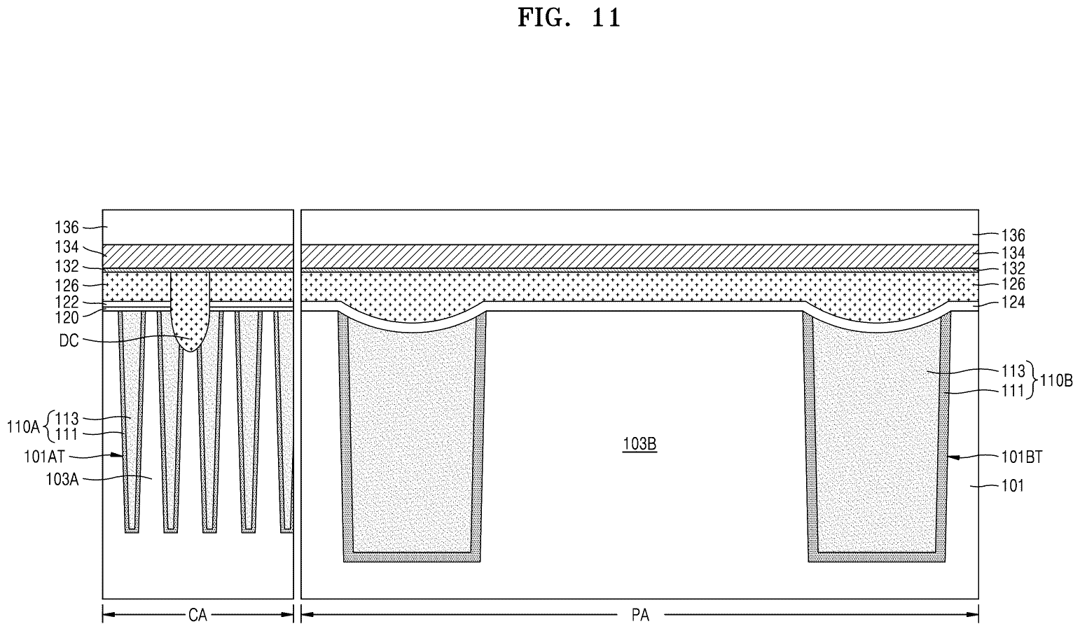

Referring to FIG. 11, a second preliminary conductive layer 132, a third preliminary conductive layer 134, and a capping layer 136 may be sequentially formed on the first preliminary conductive layer 126 and the direct contact DC in the cell area CA and the core area PA.

Each of the second preliminary conductive layer 132 and the third preliminary conductive layer 134 may include TiN, TiSiN, W, tungsten silicide, or a combination thereof, but is not limited thereto. In some example embodiments, the second preliminary conductive layer 132 may include TiSiN, and the third preliminary conductive layer 134 may include W. The capping layer 136 may include a silicon nitride layer.

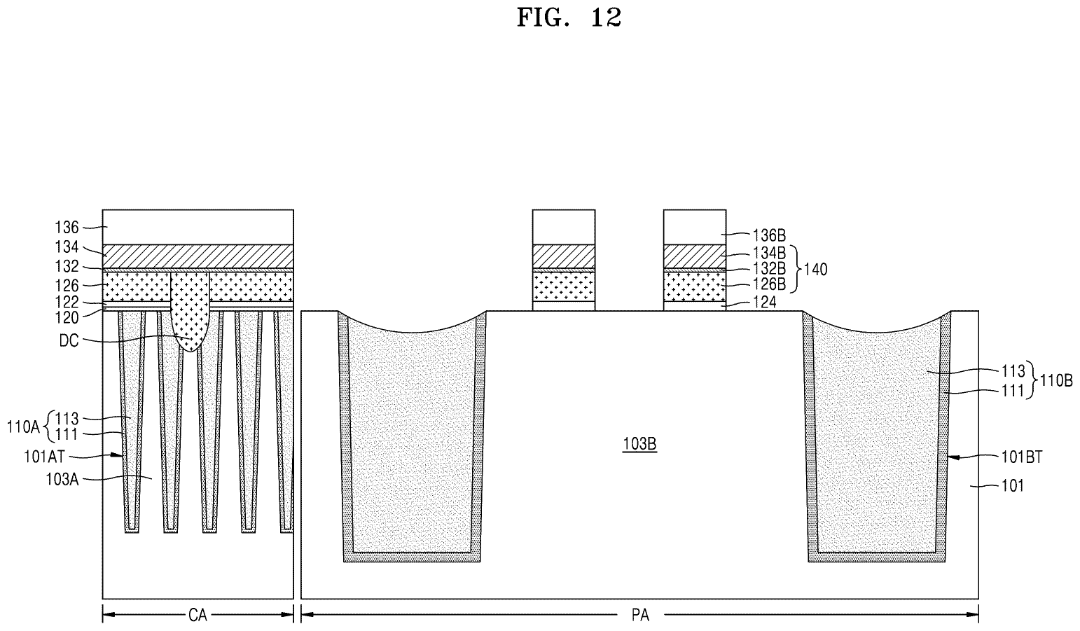

Referring to FIG. 12, the cell area CA may be covered with a mask pattern (not illustrated), and in the core area PA, the gate dielectric layer 124, the first preliminary conductive layer 126, the second preliminary conductive layer 132, the third preliminary conductive layer 134, and the capping layer 136 may be patterned.

As a result of the patterning, in the core area PA, the gate electrode 140, for the peripheral circuit, including the first core conductive pattern 126B, the second core conductive pattern 132B, and the third core conductive pattern 134B may be formed on the gate dielectric layer 124. The gate electrode 140 may be covered by the core capping pattern 136B.

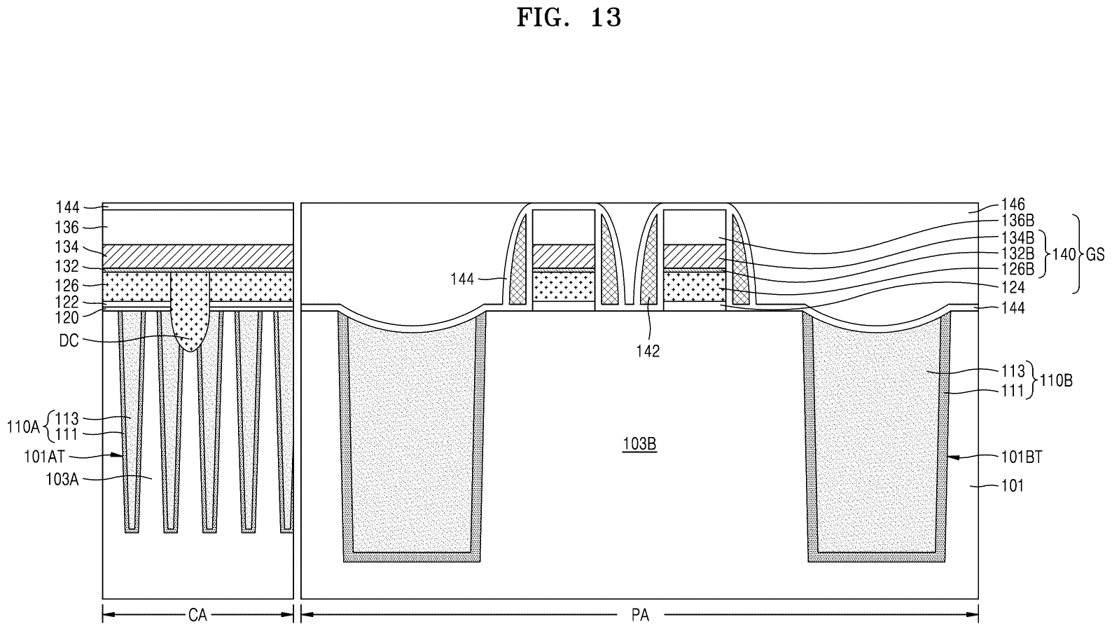

Referring to FIG. 13, an insulating thin layer 144 may be formed in the cell area CA and the core area PA.

The insulating thin layer 144 may be formed to cover the capping layer 136 in the cell area CA, surround the insulating spacer 142 formed on both sidewalls of the gate structure GS in the core area PA, and cover the substrate 101 and the gate structure GS. For example, the gate structure GS may have a stacked structure including the gate dielectric layer 124, the gate electrode 140, and the core capping pattern 136B.

The insulating spacer 142 may include a silicon oxide layer, a silicon nitride layer, or a combination thereof, and the insulating thin layer 144 may include a silicon nitride layer, but the embodiments are not limited thereto.

Next, the interlayer insulating layer 146 may be formed flat to surround the gate structure GS and the insulating thin layer 144. The interlayer insulating layer 146 may include a silicon oxide layer formed by using an HDP process or an FCVD process, but is not limited thereto.

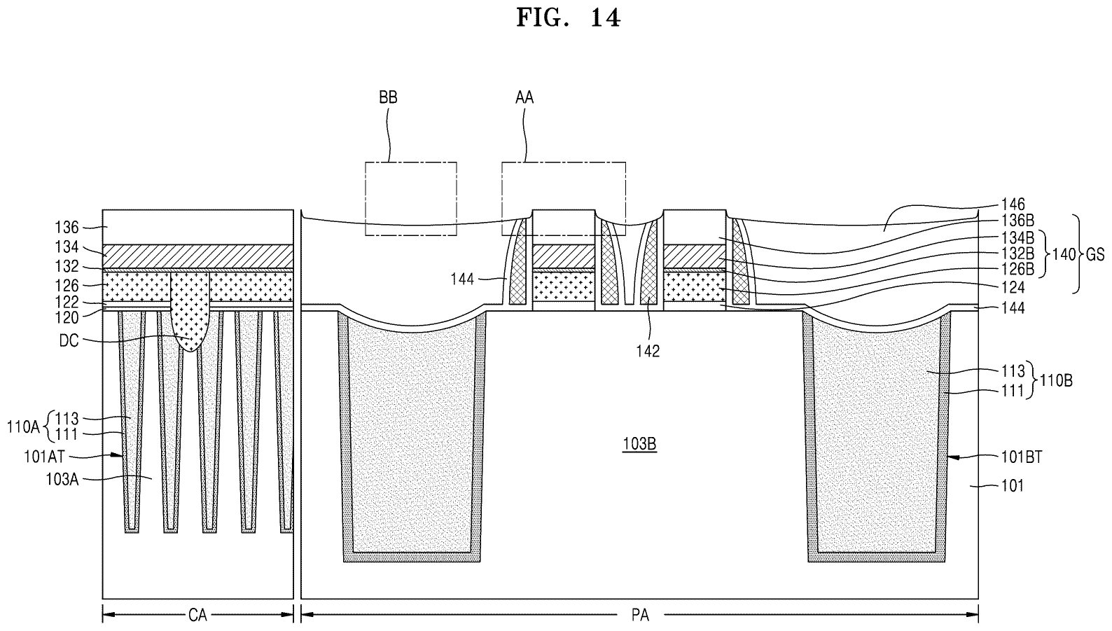

Referring to FIG. 14, a polishing process may be performed on the insulating thin layer 144 so that the upper surface of the capping layer 136 is exposed in the cell area CA, and the upper surface of the core capping pattern 136B and the upper surface of the interlayer insulating layer 146 are exposed in the core area PA.

The polishing process may include a grinding process, a chemical mechanical polishing (CMP) process, an etch-back process, etc. In the polishing process, the capping layer 136 in the cell area CA and the core capping pattern 136B in the core area PA may function as etch stop layers. Accordingly, like in portion AA, in the core area PA, as the insulating thin layer 144 on both sidewalls of the core capping pattern 136B is polished, the upper surface of the insulating spacer 142 may also be exposed.

According to the polishing process, like in portion BB, the interlayer insulating layer 146, which is greatly affected by the polishing process due to a relatively wide exposed area thereof, may have a concavely rounded upper surface in the downward direction.

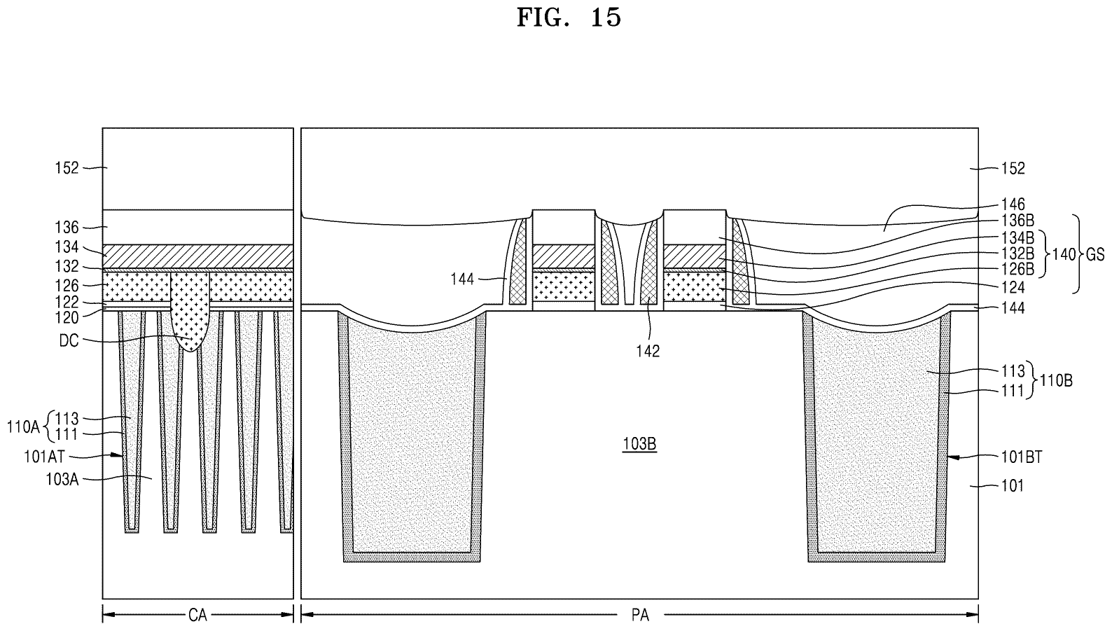

Referring to FIG. 15, the upper insulating layer 152 may be formed on the capping layer 136 in the cell area CA, and on the core capping pattern 136B and the interlayer insulating layer 146 in the core area PA.

In some example embodiments, the upper insulating layer 152 may include a silicon nitride layer. For example, in the cell area CA, the capping layer 136 and the upper insulating layer 152 may form a bonding interface between the silicon nitride layers. In the core area PA, the core capping pattern 136B and the upper insulating layer 152 may form a bonding interface between the silicon nitride layers.

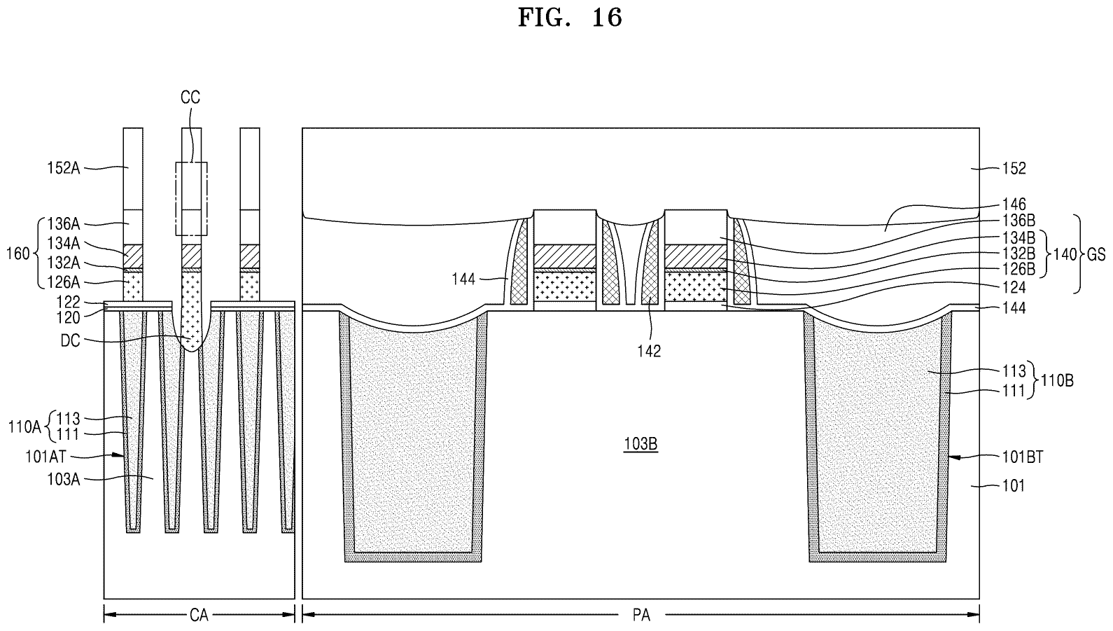

Referring to FIG. 16, by using the photo-lithography process in the cell area CA, firstly, the upper insulating layer 152 and the capping layer (refer to 136 in FIG. 15) may be patterned.

As a result of the patterning, in the cell area CA, the upper insulating pattern 152A and the cell capping pattern 136A, which are to be used as etching masks for forming the plurality of bit line structures 160, may be formed. Like in portion CC, the upper insulating pattern 152A and the cell capping pattern 136A may form a bonding interface between the silicon nitride layers.

By etching a portion of the lower structure by using the upper insulating pattern 152A and the cell capping pattern 136A as etching masks, the plurality of bit line structures 160 may be formed in the cell area CA.

In the cell area CA, by etching exposed portions of the first preliminary conductive layer 126, the second preliminary conductive layer 132, and the third preliminary conductive layer 134 by using the upper insulating pattern 152A and the cell capping pattern 136A as etching masks, the first cell conductive pattern 126A, the second cell conductive pattern 132A, and the third cell conductive pattern 134A may be formed.

In the inventive concepts, each of the plurality of bit line structures 160 may include the cell capping pattern 136A as a component. The plurality of bit line structures 160 may be electrically connected to the cell active region 103A of the substrate 101 via the direct contact DC.

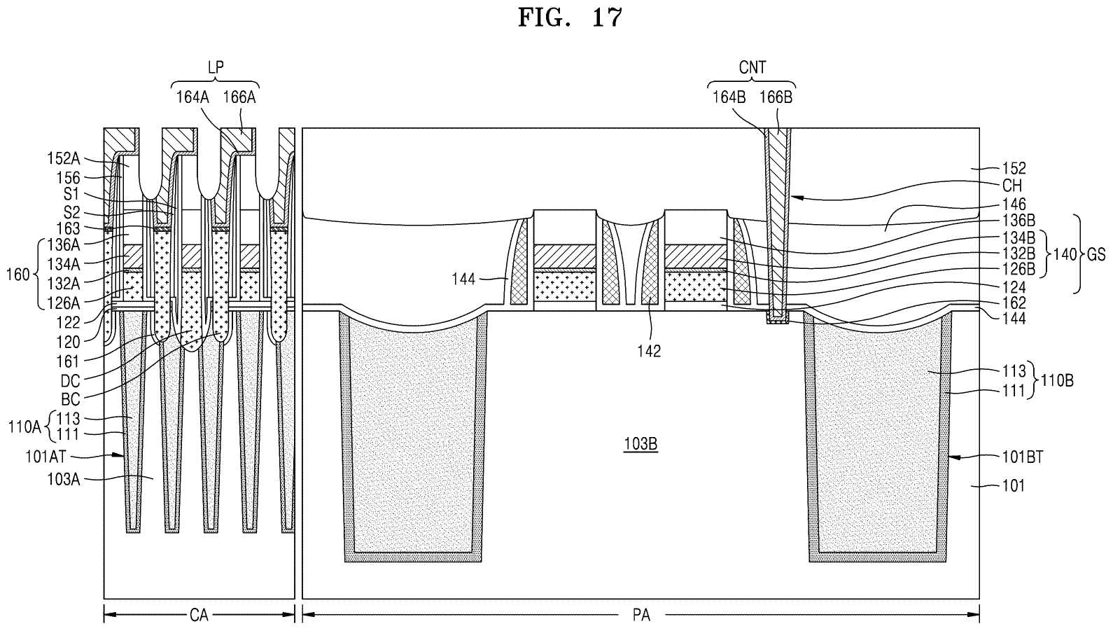

Referring to FIG. 17, the plurality of buried contacts BC may be formed in spaces between adjacent ones of the plurality of bit line structures 160 in the cell area CA, and the plurality of landing pads LP respectively connected to the plurality of buried contacts BC may be formed.

In the cell area CA, the insulating liner 156 and the spacer structures S1 and S2 covering the insulating liner 156 may be formed on the sidewalls of each of the plurality of bit line structures 160. In some example embodiments, the spacer structures S1 and S2 may include a silicon oxide layer, a silicon nitride layer, air, or a combination thereof.

Next, after a plurality of pattern structures (not visible in the cross-sectional view of FIG. 17), which limit a plurality of holes for forming the plurality of buried contacts BC in the spaces between adjacent ones of the plurality of bit line structures 160, are formed, the cell active region 103A of the substrate 101 may be exposed through the plurality of holes. The first metal silicide layer 161 may be formed on the exposed surface of the cell active region 103A. In some example embodiments, the plurality of pattern structures may include a silicon nitride layer, a silicon oxide layer, or a combination thereof.

Next, a conductive layer may be filled in a lower portion of the inside of each of the plurality of holes, and the plurality of buried contacts BC respectively connected to the plurality of cell active regions 103A may be formed.

In some example embodiments, the first metal silicide layer 161 may include cobalt silicide, but is not limited thereto. In some example embodiments, the first metal silicide layer 161 may be omitted. The plurality of buried contacts BC may include doped polysilicon.

Next, the second metal silicide layer 163 may be formed on the plurality of buried contacts BC respectively inside the plurality of holes between adjacent ones of the plurality of bit line structures 160. In some example embodiments, the second metal silicide layer 163 may include cobalt silicide, but is not limited thereto. In some example embodiments, the second metal silicide layer 163 may be omitted.

A contact hole CH, which exposes the core active region 103B by penetrating a portion of the interlayer insulating layer 146 and the upper insulating layer 152, may be formed. A core metal silicide layer 162 may be formed on the surface of the core active region 103B exposed through the contact hole CH. In some example embodiments, the core metal silicide layer 162 may include cobalt silicide, but is not limited thereto. In some example embodiments, the core metal silicide layer 162 may be omitted.

Next, a preliminary conductive barrier layer and a preliminary conductive layer may be sequentially formed in the plurality of holes on second metal silicide layer 163 in the cell area CA to fill the plurality of holes, and in the contact hole CH on the core metal silicide layer 162 in the core area PA to fill the contact hole CH.

Next, the preliminary conductive barrier layer and the preliminary conductive layer may be etched back so that the conductive barrier layer and the conductive layer are formed in the cell area CA and the core area PA.

As a result of the etching, a portion of the conductive barrier layer and a portion of the conductive layer in the cell area CA may be respectively formed on the second metal silicide layer 163 as the first conductive barrier layer 164A and a first conductive layer 166A covering the plurality of bit line structures 160, to vertically overlap a portion of the plurality of bit line structures 160 while filling the inside of the plurality of holes.

As a result of the etching, a portion of the conductive barrier layer and a portion of the conductive layer in the core area PA may be formed as a second conductive barrier layer 164B and the second conductive layer 166B, which fill the inside of the contact hole CH.

Next, in the cell area CA, a mask pattern (not illustrated) exposing a portion of the first conductive layer 166A may be formed on the first conductive layer 166A, and then the first conductive barrier layer 164A, the first conductive layer 166A, and the insulating layers around the first conductive barrier layer 164A and the first conductive layer 166A may be etched by using the mask pattern as an etching mask, to form the plurality of landing pads LP as the remaining portions of the first conductive barrier layer 164A and the first conductive layer 166A. In the core area PA, the second conductive barrier layer 164B and the second conductive layer 166B, which are inside the contact hole CH, may constitute the contact plug CNT.

Next, although not illustrated, in the cell area CA, a plurality of capacitor structures electrically and respectively connected to the plurality of landing pads LP may be formed, and a multilayer wiring structure may be formed in the core area PA, to form the semiconductor device 10 according to some example embodiments of the inventive concepts.

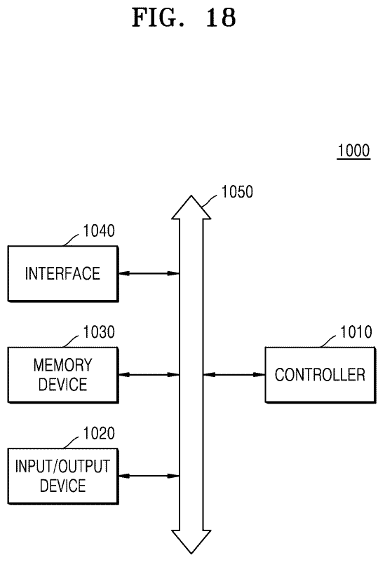

FIG. 18 is a configuration diagram of a system 1000 including a semiconductor device, according to some example embodiments.

Referring to FIG. 18, the system 1000 may include a controller 1010, an input/output device 1020, a memory device 1030, an interface 1040, and a bus 1050.

The system 1000 may include a mobile system or a system transceiving information. In some example embodiments, the mobile system may include a portable computer, a web tablet, a mobile phone, a digital music player, or a memory card.

The controller 1010 may be used for controlling execution programs in the system 1000, and may include a micro-processor, a digital signal processor, a micro-controller, or a similar device.

The input/output device 1020 may be used to input or output data of the system 1000. The system 1000 may be connected to an external device, for example, a personal computer or a network by using the input/output device 1020, and may exchange data with the external device. The input/output device 1020 may include, for example, a touch screen, a touch pad, a keyboard, or a display.

The memory device 1030 may store data for an operation of the controller 1010, or may store data processed by the controller 1010. The memory device 1030 may include any one of the semiconductor devices 10 and 20 according to some example embodiments as described with reference to FIGS. 1-17.

The interface 1040 may include a data transmission path between the system 1000 and an external device. The controller 1010, the input/output device 1020, the memory device 1030, and the interface 1040 may communicate with each other via the bus 1050.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

While the inventive concepts has been particularly shown and described with reference to some example embodiments thereof, it will be understood that various change in form and details may be made therein without departing from the spirit and scope of the following claims.

What is claimed is:

1. A semiconductor device comprising:
a substrate including a cell area and a core area surrounding the cell area, the cell area including a cell active region and the core area including a core active region;
a direct contact and a bit line structure both in the cell area, the direct contact being connected to the cell active region and the bit line structure being in contact with the direct contact, the bit line structure including a cell capping pattern at an upper portion thereof;
a gate structure on the substrate in the core area, the gate structure including a core capping pattern at an upper portion thereof;
an insulating spacer on both sidewalls of the gate structure;
an insulating thin layer conformally surrounding the insulating spacer; and
an upper insulating layer covering the cell capping pattern of the bit line structure in the cell area, and covering the core capping pattern of the gate structure in the core area,
wherein in the cell area, the upper insulating layer contacts the cell capping pattern, and
wherein in the core area, the upper insulating layer penetrates the insulating thin layer and contacts each of the core capping pattern, the insulating spacer, and the insulating thin layer.

2. The semiconductor device of claim 1, wherein
a lowermost surface of the upper insulating layer in the cell area is at a higher vertical level than a lowermost surface of the upper insulating layer in the core area.

3. The semiconductor device of claim 2, wherein
in the core area the lowermost surface of the upper insulating layer is at a lower vertical level than an uppermost surface of the core capping pattern.

4. The semiconductor device of claim 1, wherein
the insulating thin layer conformally contacts the both sidewalls of the gate structure and an upper surface of the substrate.

5. The semiconductor device of claim 4, further comprising:
a trench isolation in the core area, the trench isolation dividing the core active region, and the trench isolation including a concavely rounded upper surface,
wherein the insulating thin layer conformally covers the concavely rounded upper surface of the trench isolation.

6. The semiconductor device of claim 5, further comprising:
an interlayer insulating layer in the core area, the interlayer insulating layer surrounding a periphery of the gate structure, and the interlayer insulating layer including a concavely rounded upper surface,
wherein the concavely rounded upper surface of the trench isolation corresponds to the concavely rounded upper surface of the interlayer insulating layer.

7. The semiconductor device of claim 4, wherein
a lowermost surface of the insulating spacer is at a higher vertical level than a lowermost surface of the gate structure, and
an uppermost surface of the insulating spacer is at a lower vertical level than an uppermost surface of the gate structure.

8. The semiconductor device of claim 7, wherein
the uppermost surface of the insulating spacer contacts the upper insulating layer, and
sidewalls of the insulating spacer and the lowermost surface of the insulating spacer contact the insulating thin layer.

9. The semiconductor device of claim 1, wherein
the cell capping pattern and the core capping pattern comprise a first insulating material formed by an identical manufacturing process, and
the upper insulating layer comprises a second insulating material identical to the first insulating material.

10. The semiconductor device of claim 9, wherein
the first insulating material and the second insulating material are silicon nitride layers, and
the bit line structure comprises a bonding interface between the silicon nitride layers constituting the upper insulating layer and the cell capping pattern.

11. A semiconductor device comprising:
a substrate including a cell area and a core area surrounding the cell area, the cell area including a cell active region and the core area including a core active region;
a direct contact and a bit line structure both in the cell area, the direct contact being connected to the cell active region and the bit line structure being in contact with the direct contact, the bit line structure including a cell capping pattern at an upper portion thereof;
a gate structure on the substrate in the core area, the gate structure including a core capping pattern at an upper portion thereof;
an insulating spacer on both sidewalls of the gate structure;
an insulating thin layer conformally surrounding the insulating spacer;
an interlayer insulating layer surrounding a periphery of the gate structure in the core area;
a natural oxide layer covering the cell capping pattern of the bit line structure in the cell area, and the natural oxide layer conformally covering the core capping pattern of the gate structure and the interlayer insulating layer in the core area; and
an upper insulating layer covering the natural oxide layer in the cell area and the core area,
wherein the natural oxide layer is between the cell capping pattern and the upper insulating layer in the cell area, and
wherein in the core area, the natural oxide layer penetrates the insulating thin layer and contacts each of the core capping pattern, the insulating spacer, and the insulating thin layer.

12. The semiconductor device of claim 11, wherein
a lowermost surface of the upper insulating layer in the cell area is at a higher vertical level than a lowermost surface of the upper insulating layer in the core area, and
in the core area, the lowermost surface of the upper insulating layer is at a lower vertical level than an uppermost surface of the core capping pattern.

13. The semiconductor device of claim 11, wherein
the insulating thin layer conformally contacts the both sidewalls of the gate structure and an upper surface of the substrate,
an uppermost surface of the insulating spacer contacts the natural oxide layer, and
sidewalls and a lower surface of the insulating spacer contact the insulating thin layer.

14. The semiconductor device of claim 11, wherein
the interlayer insulating layer in the core area includes a concavely rounded upper surface, and
the natural oxide layer conformally covers the concavely rounded upper surface of the interlayer insulating layer.

15. The semiconductor device of claim 11, wherein
the cell capping pattern and the core capping pattern comprise a silicon nitride layer formed by using an identical manufacturing process,
the upper insulating layer comprises a silicon nitride layer, and
the bit line structure comprises the natural oxide layer between the silicon nitride layers constituting the upper insulating layer and the cell capping pattern.

16. A semiconductor device comprising:
a substrate including a cell area and a core area surrounding the cell area, the cell area including a cell active region and the core area including a core active region;
a direct contact and a bit line structure both in the cell area, the direct contact being connected to the cell active region and the bit line structure being in contact with the direct contact, the bit line structure including a cell conductive pattern and a cell capping pattern;
a gate structure on the substrate in the core area, the gate structure including a core conductive pattern and a core capping pattern;
an insulating spacer on both sidewalls of the gate structure;
an insulating thin layer conformally surrounding the insulating spacer;
an interlayer insulating layer surrounding a periphery of the gate structure in the core area; and
an upper insulating layer covering the cell capping pattern of the bit line structure in the cell area, and the upper insulating layer conformally covering the core capping pattern of the gate structure and the interlayer insulating layer in the core area,
wherein in the cell area, the upper insulating layer contacts the cell capping pattern, and
wherein in the core area, the interlayer insulating layer has a concavely rounded upper surface and the upper insulating layer has a convexly rounded lower surface corresponding to the concavely rounded upper surface of the interlayer insulating layer.

17. The semiconductor device of claim 16, further comprising:
a trench isolation in the core area, the trench isolation dividing the core active region, and the trench isolation including a concavely rounded upper surface,
wherein the insulating thin layer conformally covers the concavely rounded upper surface of the trench isolation.

18. The semiconductor device of claim 17, wherein
the interlayer insulating layer has a convexly rounded lower surface corresponding to the concavely rounded upper surface of the trench isolation.

19. The semiconductor device of claim 18, wherein
the concavely rounded upper surface of the trench isolation and the concavely rounded upper surface of the interlayer insulating layer correspond to the convexly rounded lower surface of the interlayer insulating layer and the convexly rounded lower surface of the upper insulating layer, respectively.

20. The semiconductor device of claim 19, wherein
the cell capping pattern and the core capping pattern comprise a first insulating material formed by an identical manufacturing process,
the upper insulating layer comprises a second insulating material identical to the first insulating material, and
the bit line structure comprises a bonding interface between the first insulating material and the second insulating material.
